(19) United States
(12) Patent Application Publication
(10) Pub. No.: US 2024/0347436 A1
(43) Pub. Date: Oct. 17, 2024

(54) METHOD FOR PRODUCING SEMICONDUCTOR DEVICE, AND SEMICONDUCTOR DEVICE

(71) Applicant: Resonac Corporation, Minato-ku, Tokyo (JP)

(72) Inventors: Tomoaki SHIBATA, Minato-ku, Tokyo (JP); Shizu FUKUZUMI, Minato-ku, Tokyo (JP); Toshiaki SHIRASAKA, Minato-ku, Tokyo (JP)

(21) Appl. No.: 18/290,846

(22) PCT Filed: Jul. 28, 2021
(86) PCT No.: PCT/JP2021/027958

§ 371 Date: Jan. 22, 2024

(51) Int. Cl. H01L 23/498; H01L 23/00; H01L 23/29; H01L 23/31; H01L 23/532; H01L 25/065

(52) U.S. Cl. CPC H01L 23/49827; H01L 23/293; H01L 23/3121; H01L 23/49816; H01L 23/53295; H01L 24/13; H01L 25/0652; H01L 2224/13024; H01L 2924/1811; H01L 2924/186

(57) ABSTRACT

A method for producing a semiconductor device includes preparing a first semiconductor chip including a first chip main body, and a first insulating film and a first electrode, preparing a second semiconductor chip including a second chip main body, and a second insulating film and a second electrode, attaching the first insulating film of the first semiconductor chip and the second insulating film of the second semiconductor chip to each other, bonding the first electrode of the first semiconductor chip and the second electrode of the second semiconductor chip, encapsulating the second semiconductor chip provided on the first semiconductor chip with an encapsulating resin, forming a via hole in an encapsulating body formed of the encapsulating resin, and filling a conductive material in the via hole such that electric connection to at least one of the first electrode and the second electrode is attained.

### TECHNICAL FIELD

The present disclosure relates to a method for producing a semiconductor device, and a semiconductor device.

### BACKGROUND ART

Recently, three-dimensional packaging has been considered to improve the integration degree of LSI. Patent Literature 1 and Non-Patent Literature 1 disclose examples of three-dimensional packaging of semiconductor chips.

### CITATION LIST

### Patent Literature

Patent Literature 1: Specification of U.S. Patent Application Publication No. 2018/0082964

### Non-Patent Literature

Non-Patent Literature 1: F. C. Chen et al., “System on Integrated Chips (SoIC™) for 3D Heterogeneous Integration”, 2019 IEEE 69th Electronic Components and Technology Conference (ECTC), p. 594-599 (2019)

### SUMMARY OF INVENTION

### Technical Problem

In the three-dimensional packaging of the semiconductor chips, it is required to further improve the connection structure of the semiconductor chips.

An object of the present disclosure is to provide a method for producing a semiconductor device and a semiconductor device which enable high-density packaging in three-dimensional packaging.

### Solution to Problem

As one aspect, the present disclosure relates to a method for producing a semiconductor device. The method for producing a semiconductor device, includes: preparing a first semiconductor chip including a first chip main body, and a first insulating film and a first electrode provided on one surface of the first chip main body; preparing at least one second semiconductor chip including a second chip main body, and a second insulating film and a second electrode provided on one surface of the second chip main body; attaching the first insulating film of the first semiconductor chip and the second insulating film of the second semiconductor chip to each other; bonding the first electrode of the first semiconductor chip and the second electrode of the second semiconductor chip; encapsulating the second semiconductor chip provided on the first semiconductor chip with an encapsulating resin; forming at least one via hole in an encapsulating body formed of the encapsulating resin; and filling a conductive material in the via hole such that electric connection to at least one of the first electrode and the second electrode is attained to form a conduction via.

In the method for producing a semiconductor device, the first semiconductor chip and the second semiconductor chip are bonded by so-called hybrid bonding, and then, the second semiconductor chip is encapsulated, and the conduction via is formed in the encapsulating body. In this case, since the conduction via is formed after encapsulating, it is possible to form the conduction via with a high density. Accordingly, in three-dimensional packaging in which the second semiconductor chip is provided on the first semiconductor chip, it is possible to perform high-density packaging.

In the method for producing a semiconductor device described above, at least one of the first insulating film and the second insulating film may include an inorganic insulating material. In this case, it is possible to prepare the semiconductor device with a finer configuration. Both of the first insulating film and the second insulating film may include the inorganic insulating material, and in this case, the inorganic materials are likely to be firmly bonded, and it is possible to increase a bonding strength between the semiconductor chips, and improve connection reliability as the semiconductor device.

In the method for producing a semiconductor device described above, at least one of the first insulating film and the second insulating film may include an organic insulating material. In this case, impurities (debris) or the like attached onto the chip surface are absorbed in the insulating film by the organic material that is a comparatively soft material, and it is possible to reduce a connection failure between the semiconductor chips. The organic insulating material included in the insulating film may be polyimide, a polyimide precursor, polyamide imide, benzocyclobutene (BCB), polybenzoxazole (PBO), or a PBO precursor. Since such a material is liquid or soluble in a solvent, the insulating film is easily prepared, for example, by spin coating or the like, and a thin film is easily formed. In addition, such a material has high heat resistance, thereby being capable of withstanding a high temperature when bonding the first semiconductor chip to the second semiconductor chip, and the chips can be more reliably bonded. A part of each of the first insulating film and the second insulating film may be formed of the inorganic insulating material, and the other (for example, the surface side) may be formed of the organic insulating material.

In the method for producing a semiconductor device described above, in the attaching, the first insulating film and the second insulating film may be bonded with each other by room-temperature bonding. In this case, the first insulating film and the second insulating film can be easily bonded with each other, without considering thermal expansion or the like. Since the bonding is performed at a room temperature, it is possible to reduce the influence of heat on the first semiconductor chip and the second semiconductor chip.

The method for producing a semiconductor device described above may further include grinding a surface of the encapsulating body. In this case, since the unevenness or a variation in the surface roughness on the surface of the encapsulating body is reduced, it is possible to more accurately form a re-distribution layer or a normal wiring layer with a high density. In this case, in the grinding, the encapsulating body may be ground such that surface roughness (a Ra value) of the encapsulating body is 1 μm or less, even more preferably 0.5 μm or less, and most preferably 0.1 μm or less. Accordingly, it is possible to form wiring with a fine pattern shape. In the grinding, the encapsulating body may be ground such that a thickness of the encapsulating body between the surface of the encapsulating body and the second semiconductor chip is 300 μm or less, even more preferably 250 μm or less, and most preferably 200 μm or less. Alternatively, the surface of the second semiconductor chip (on a side opposite to a surface for forming a terminal electrode and an insulating layer) may be exposed. Accordingly, it is possible to reduce the size of a package, reduce warpage, and improve heat dissipation. The surface roughness (the Ra value) used herein, for example, is calculated by observation with an electron microscope, and indicates arithmetic mean surface roughness (JIS B 0601-2001).

The method for producing a semiconductor device described above may further include forming a re-distribution layer on the encapsulating body. In this case, it is possible to easily convert the wiring pitch of the first semiconductor chip or the like into the wiring pitch of an external device such as a wiring substrate. In this case, the re-distribution layer may be electrically connected to the first electrode of the first semiconductor chip by the conduction via formed of the conductive material.

The method for producing a semiconductor device described above may further include forming a bump on an outer surface of the re-distribution layer positioned on a side opposite to the encapsulating body. In this case, it is possible to easily attach the semiconductor device to the external device such as the wiring substrate.

In the method for producing a semiconductor device described above, the encapsulating material used in the encapsulating may be an epoxy resin or an acrylic resin. In this case, it is possible to reliably and easily perform the encapsulating of the second semiconductor chip.

In the method for producing a semiconductor device described above, in the forming of the via hole, a plurality of via holes may be formed around the second semiconductor chip, and the first electrode of the first semiconductor chip may be exposed to the plurality of via holes. Then, in the filling of the conductive material, the conductive material may be filled in each of the plurality of via holes such that electric connection to the first electrode is attained. In this case, it is possible to provide the conduction via with a higher density, and more reliably connect the first semiconductor chip to the external device or the like.

In the method for producing a semiconductor device described above, the second semiconductor chip may be a chip having a surface area smaller than that of the first semiconductor chip, and a plurality of second semiconductor chips may be bonded to the first semiconductor chip. Then, in the encapsulating, the plurality of second semiconductor chips provided on the first semiconductor chip may be collectively encapsulated with the encapsulating resin. In this case, since it is possible to bond two or more second semiconductor chips to one first semiconductor chip, it is possible to perform the three-dimensional packaging with a higher density.

As another aspect, the present disclosure relates to a semiconductor device. The semiconductor device, includes: a first semiconductor chip including a first chip main body, and a first insulating film and a first electrode provided on one surface of the first chip main body; a second semiconductor chip including a second chip main body, and a second insulating film and a second electrode provided on one surface of the second chip main body, and being provided on the first semiconductor chip; an encapsulating body covering the second semiconductor chip provided on the first semiconductor chip; and a conduction via filled in a via hole provided in the encapsulating body to be electrically connected to at least one of the first electrode and the second electrode.

In the semiconductor device, the first semiconductor chip and the second semiconductor chip are firmly bonded with each other by so-called hybrid bonding, and the conduction via is formed in the encapsulating body encapsulating the second semiconductor chip. In this case, since the conduction via is formed in the encapsulating body, it is possible to form the conduction via with a high density. Accordingly, in three-dimensional packaging in which the second semiconductor chip is provided on the first semiconductor chip, it is possible to perform high-density packaging.

The semiconductor device described above may further include a re-distribution layer provided on a surface of the encapsulating body on a side opposite to the first semiconductor chip, in which the re-distribution layer may be electrically connected to the first electrode of the first semiconductor chip by the conduction via. It is possible to easily convert the wiring pitch of the first semiconductor chip or the like into the wiring pitch of an external device such as a wiring substrate.

### Advantageous Effects of Invention

According to the present disclosure, it is possible to perform the high-density packaging in the three-dimensional packaging.

### BRIEF DESCRIPTION OF DRAWINGS

FIG. 1 is a sectional view schematically illustrating an example of a semiconductor device according to one embodiment of the present invention.

FIGS. 2A and 2B are sectional views each illustrating a sectional surface of each semiconductor chip used to produce the semiconductor device illustrated in FIG. 1, in which FIG. 2A illustrates a sectional surface of one semiconductor chip, and FIG. 2B illustrates a sectional surface of the other semiconductor chip.

FIG. 3 is a schematic sectional view illustrating one step of a method for producing a semiconductor device according to one embodiment of the present invention, and illustrates a step of bonding one semiconductor chip to the other semiconductor chip.

FIGS. 4A to 4C are diagrams for sequentially describing bonding between the semiconductor chips illustrated in FIG. 3.

FIGS. 5A to 5C are schematic sectional views illustrating each step of the method for producing a semiconductor device according to one embodiment of the present invention, subsequent to FIG. 3.

FIGS. 6A to 6C are schematic sectional views illustrating each step of the method for producing a semiconductor device according to one embodiment of the present invention, subsequent to FIGS. 5A to 5C.

### DESCRIPTION OF EMBODIMENTS

Hereinafter, an embodiment according to the present invention will be described in detail with reference to the drawings. In the following description, the same reference numerals will be applied to the same or corresponding parts, and the repeated description will be omitted. A positional relationship such as the left, right, top, and bottom is based on a positional relationship illustrated in the drawings, unless otherwise specified. A dimension ratio in the drawings is not limited to the illustrated ratio.

In this specification, the term “layer” includes not only a structure in which a layer is formed on the entire surface but also a structure in which a layer is formed on a part of the surface when observed as a plan view. In this specification, the term “step” includes not only an independent step but also a step that is not explicitly distinguishable from other steps insofar as a desired function of the step is attained. A numerical range represented by using “to” indicates a range including numerical values described before and after “to” as the minimum value and the maximum value, respectively.

### (Configuration of Semiconductor Device)

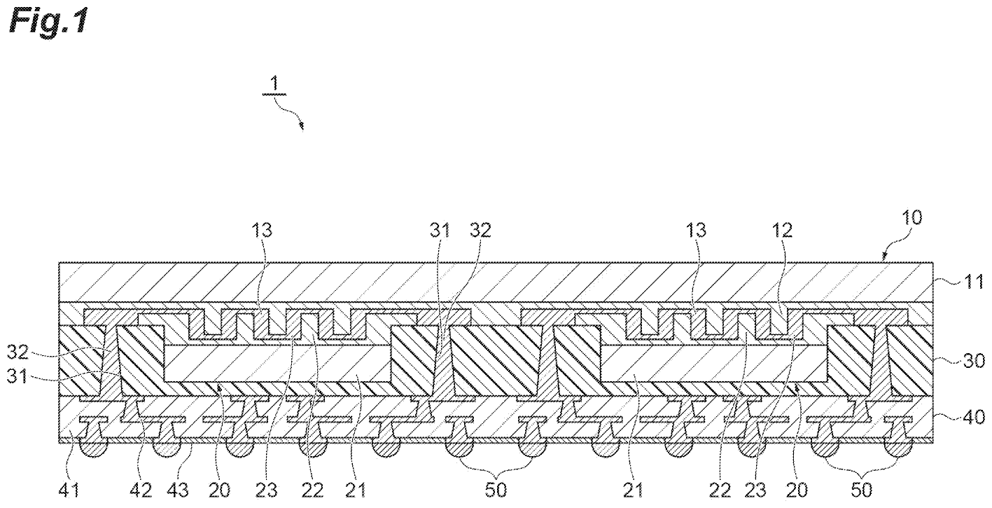

FIG. 1 is a sectional view schematically illustrating an example of a semiconductor device according to this embodiment. As illustrated in FIG. 1, a semiconductor device 1, for example, is an example of a semiconductor package, and includes a first semiconductor chip 10, at least one second semiconductor chip 20, an encapsulating body 30, a re-distribution layer 40, and a plurality of bumps 50. In the semiconductor device 1, one or more second semiconductor chips 20 (in this embodiment, for example, two second semiconductor chips 20) are mounted on the first semiconductor chip 10 to configure a three-dimensional packaging structure. The first semiconductor chip 10, for example, is a large scale integrated circuit (LSI) chip, a complementary metal oxide semiconductor (CMOS) sensor, or the like. The second semiconductor chip 20 is a chip having a surface area smaller than that of the first semiconductor chip 10, and for example, is a semiconductor chip such as LSI or a memory. The first semiconductor chip 10 and the second semiconductor chip 20 may be other types of semiconductor chips.

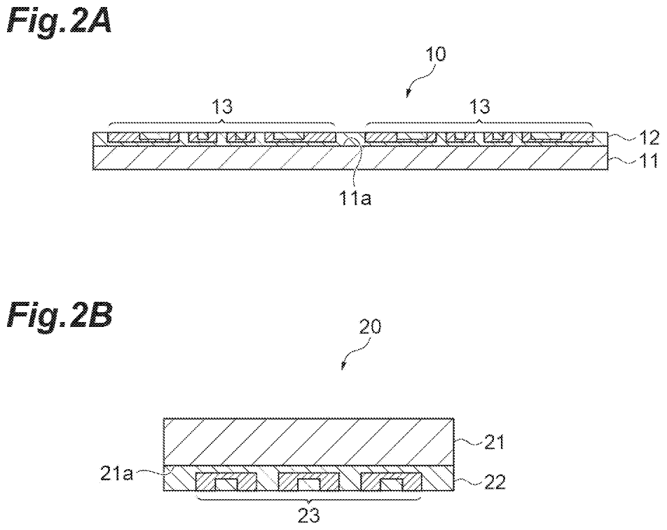

The first semiconductor chip 10 includes a chip main body 11 (a first chip main body), an insulating film 12 (a first insulating film), and terminal electrodes 13 (a first electrode) (also refer to FIG. 2A). The chip main body 11 is the main part of the first semiconductor chip 10 on which an integrated circuit or the like is formed. The insulating film 12 is an insulating film that is formed of an inorganic insulating material or an organic insulating material, and provided on an inner surface 11a (one surface) of the chip main body 11. The inorganic insulating material forming the insulating film 12, for example, is silicon dioxide (SiO₂), silicon nitride (SiN), silicon oxynitride (SiON), or the like. The organic insulating material forming the insulating film 12, for example, is polyimide, a polyimide precursor, polyamide imide, benzocyclobutene (BCB), polybenzoxazole (PBO), a PBO precursor, or the like. A part (for example, the surface side) of the insulating film 12 may be formed of the organic insulating material, and the remaining part may be formed of the inorganic insulating material. Since the organic insulating material has an elastic modulus (a Young's modulus) lower than that of the inorganic insulating material and is a soft material, in a case where the organic insulating material is disposed on the surface side, it is possible to absorb impurities (debris or the like) attached onto the surface of the first semiconductor chip 10.

The terminal electrode 13 is an electrode formed of a conductive material such as copper (Cu) in the insulating film 12. The diameter or the width of each electrode configuring the terminal electrodes 13, for example, is 0.005 μm or more and 20 μm or less. One end portion of the terminal electrode 13 is electrically connected to a connection terminal of the chip main body 11, and the other end portion of the terminal electrode 13 is formed to be exposed to the outside from the insulating film 12. The terminal electrodes 13 of the first semiconductor chip 10 are provided in accordance with the number of second semiconductor chips 20 to be mounted.

The second semiconductor chip 20 includes a chip main body 21 (a second chip main body), an insulating film 22 (a second insulating film), and terminal electrodes 23 (a second electrode) (also refer to FIG. 2B). The chip main body 21 is the main part of the second semiconductor chip 20 on which an integrated circuit or the like is formed. The insulating film 22 is an insulating film that is formed of an inorganic insulating material or an organic insulating material, and provided on an inner surface 21a (one surface) of the chip main body 21. The inorganic insulating material or the organic insulating material forming the insulating film 22 is the same as that of the insulating film 12 of the first semiconductor chip 10. The terminal electrode 23 is an electrode formed of a conductive material such as copper (Cu) in the insulating film 22. The diameter or the width of each electrode configuring the terminal electrodes 23, for example, is 0.005 μm or more and 20 μm or less, as with the terminal electrodes 13. One end portion of the terminal electrode 23 is electrically connected to a connection terminal of the chip main body 21, and the other end portion of the terminal electrode 23 is formed to be exposed from the insulating film 22.

In the first semiconductor chip 10 and the second semiconductor chip 20, by hybrid bonding described below, the insulating film 12 around the terminal electrodes 13 and the insulating film 22 around the terminal electrodes 23 are firmly attached, and the terminal electrodes 13 and the terminal electrodes 23 are bonded, with each other. According to such hybrid bonding, in the semiconductor device 1, the terminal electrodes 13 and the terminal electrodes 23 are finely bonded without misregistration.

The encapsulating body 30 is a part in which the second semiconductor chips 20 mounted (provided) on the first semiconductor chip 10 are encapsulated with an encapsulating material. The encapsulating body 30 encapsulates a region of the second semiconductor chips 20 excluding a surface provided on the first semiconductor chip 10. As a material configuring the encapsulating body 30, for example, an epoxy resin or an acrylic resin can be exemplified, and the encapsulating body 30 can be formed by curing such a resin with heat or light. In addition, a plurality of via holes 31 are formed in the encapsulating body 30. Each of the via holes 31 is a through hole penetrating from the first semiconductor chip 10 to the re-distribution layer 40, in which the terminal electrode 13 of the first semiconductor chip 10 is exposed to one end (the upper end in FIG. 1), and an electrode of the re-distribution layer 40 or a normal wiring layer is exposed to the other end. In the via hole 31, a conductive material such as copper is filled to form a conduction via 32. The conduction via 32 electrically connects the terminal electrode 13 of the first semiconductor chip 10 and a wiring electrode 42 of the re-distribution layer 40 or the like. The semiconductor device 1 includes at least one conduction via 32, but the conduction via 32 may be provided in accordance with the number of second semiconductor chips 20, or a plurality of conduction vias 32 may be provided for one second semiconductor chip 20.

The re-distribution layer 40 is a re-distribution layer (RDL) for widening the terminal pitch of the terminal electrode 13 of the first semiconductor chip 10, and for example, is composed of an insulating layer 41 such as polyimide, and the wiring electrode 42 such as copper wiring. An outer insulating layer 43 may be provided on the re-distribution layer 40 such that the terminals of the wiring electrodes 42 exposed to the outside from the insulating layer 41 are insulated from each other. The bump 50 composed of a solder ball or the like is connected to the terminal of the wiring electrode 42 of which the terminal pitch is widened by the re-distribution layer 40. Accordingly, the terminal electrode 13 of the first semiconductor chip 10 is pitch-converted (widened) and connected to the bump 50.

### (Method for Producing Semiconductor Device)

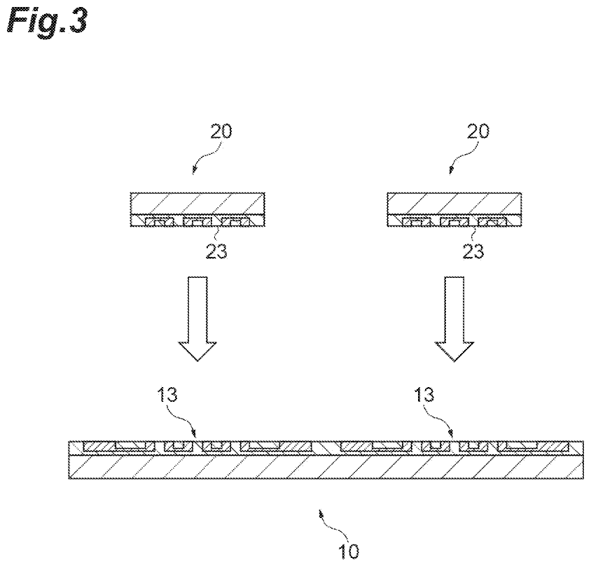

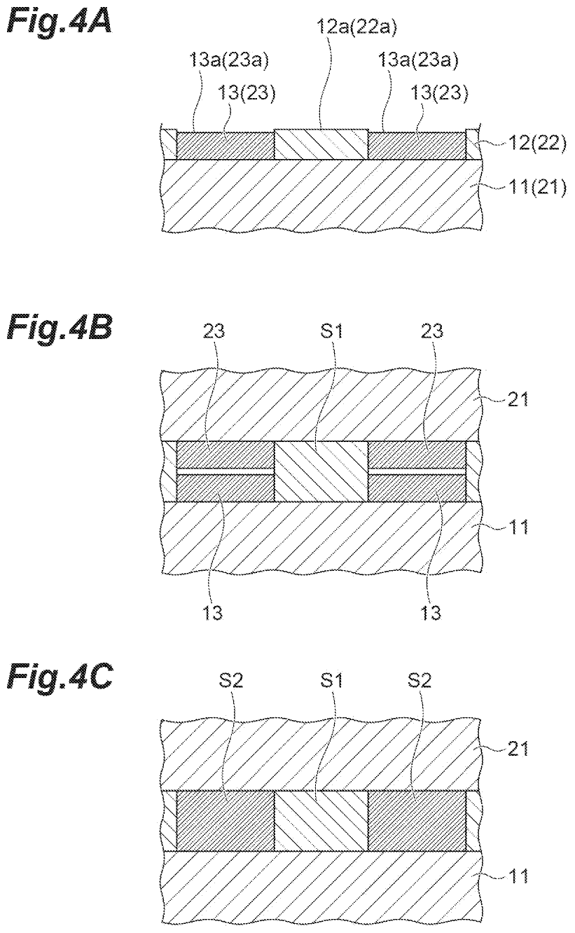

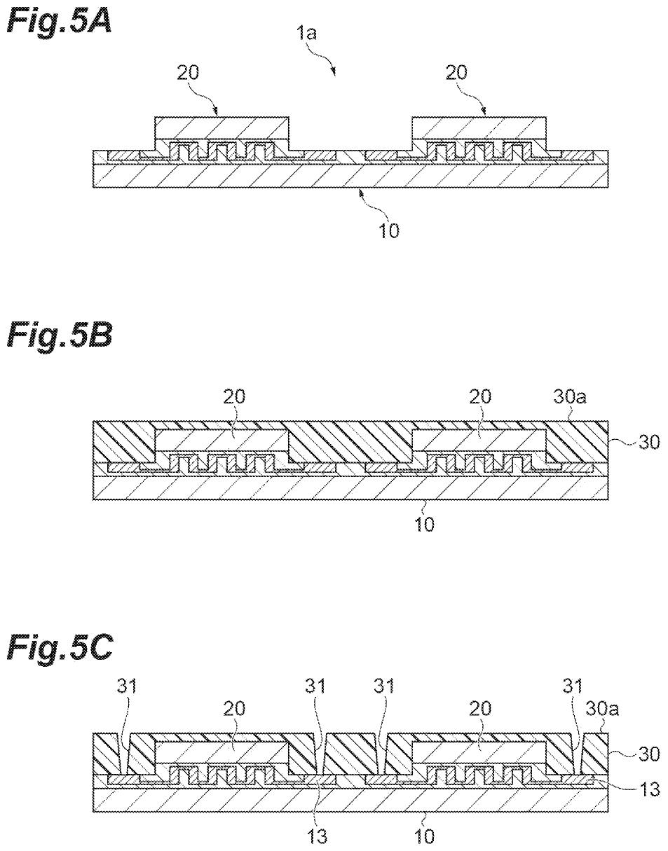

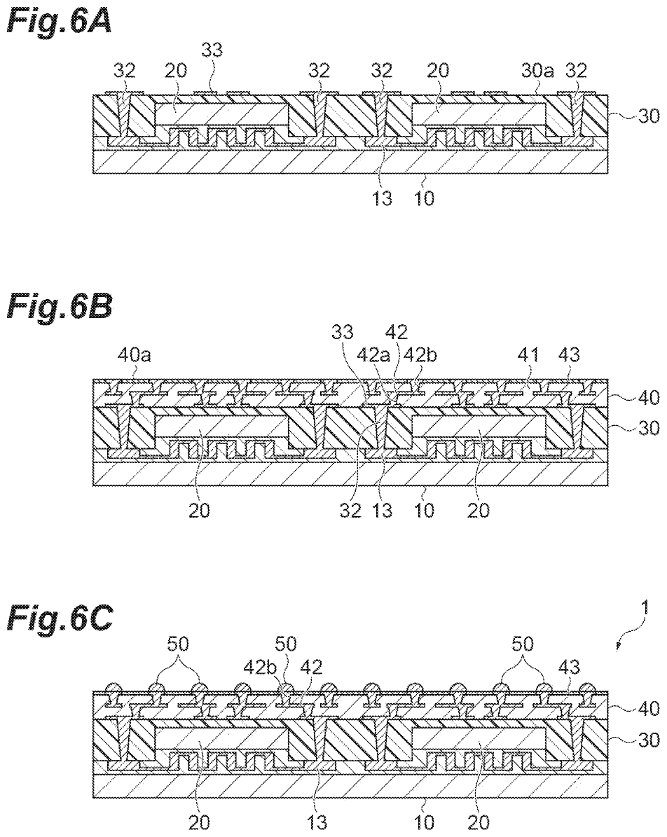

Next, a method for producing the semiconductor device 1 will be sequentially described with reference to FIGS. 2A-2C to FIGS. 6A-6C. FIGS. 2A and 2B are sectional views each illustrating the sectional surface of each semiconductor chip used to produce the semiconductor device, in which FIG. 2A illustrates the sectional surface of the first semiconductor chip, and FIG. 2B illustrates the sectional surface of the second semiconductor chip. FIG. 3 is a schematic sectional view illustrating one step of the method for producing a semiconductor device according to this embodiment, and illustrates a step of bonding the second semiconductor chips to the first semiconductor chip. FIGS. 4A to 4C are diagrams sequentially illustrating the bonding between the semiconductor chips illustrated in FIG. 3. FIGS. 5A to 5C and FIGS. 6A to 6C are schematic sectional views illustrating each step of the method for producing a semiconductor device according to this embodiment, subsequent to FIG. 3.

The semiconductor device 1, for example, can be produced via the following step (a) to step (j).

(a) A step of preparing the first semiconductor chip 10 including the chip main body 11, and the insulating film 12 and the terminal electrode 13 provided on one surface of the chip main body 11.

(b) A step of preparing at least one second semiconductor chip 20 including the chip main body 21, and the insulating film 22 and the terminal electrode 23 provided on one surface of the chip main body 21.

(c) A step of attaching the insulating film 12 of the first semiconductor chip 10 and the insulating film 22 of the second semiconductor chip 20 to each other.

(d) A step of bonding the terminal electrode 13 of the first semiconductor chip 10 and the terminal electrode 23 of the second semiconductor chip 20 to each other.

(e) A step of encapsulating the second semiconductor chip 20 provided on the first semiconductor chip 10 with the encapsulating resin to form the encapsulating body 30.

(f) A step of grinding a surface 30a of the encapsulating body 30.

(g) A step of forming at least one via hole 31 in the encapsulating body 30 formed of the encapsulating resin.

(h) A step of filling the conductive material in the via hole 31 such that electric connection to at least one of the terminal electrode 13 and the terminal electrode 23 is attained to form the conduction via 32.

(i) A step of forming the re-distribution layer 40 on the surface 30a of the encapsulating body 30.

(j) A step of forming the bump 50 on the outer surface 40a of the re-distribution layer 40 positioned on a side opposite to the encapsulating body 30.

Note that, hereinafter, the method for producing the semiconductor device 1 having a configuration in which two second semiconductor chips 20 are attached to one first semiconductor chip 10 has been described, but the combination of the semiconductor chips to be bonded is not particularly limited to such a relationship. A method for producing a semiconductor device by bonding the second semiconductor chip 20 to a substrate including a plurality of first semiconductor chips 10, and finally performing singulation may be used.
[Step (a) and Step (b)]
The step (a) is a step of preparing the first semiconductor chip 10 in which semiconductor elements and an integrated circuit consisting of wiring or the like for connecting the semiconductor elements are formed. In the step (a), as illustrated in FIG. 2A, on the inner surface 11a of the chip main body 11 consisting of silicon or the like, the terminal electrodes 13 consisting of copper, aluminum, or the like are provided, and the insulating film 12 consisting of the inorganic material or the organic material is provided. The terminal electrode 13 is a terminal electrode for allowing the integrated circuit or the like formed in the first semiconductor chip 10 to penetrate through the insulating film 12 and be exposed to the outside. Each of the terminal electrodes 13 corresponds to the second semiconductor chip 20. The terminal electrode 13 may be provided after the insulating film 12 is provided on the inner surface 11a of the chip main body 11, or the insulating film 12 may be provided after the terminal electrode 13 is provided on the inner surface 11a of the chip main body 11.

The step (b) is a step of preparing the second semiconductor chip 20 in which semiconductor elements and an integrated circuit consisting of wiring or the like for connecting the semiconductor elements are formed. In the step (b), as illustrated in FIG. 2B, on the inner surface 21a of the chip main body 21 consisting of silicon or the like, the terminal electrode 23 consisting of copper, aluminum, or the like is provided, and the insulating film 22 consisting of the inorganic material or the organic material is provided. The terminal electrode 23 is a terminal electrode for allowing the integrated circuit or the like formed in the second semiconductor chip 20 to penetrate through the insulating film 22 and be exposed to the outside. The terminal electrode 23 corresponds to the terminal electrode 13 of the first semiconductor chip 10. The terminal electrode 23 may be provided after the insulating film 22 is provided on the inner surface 21a of the chip main body 21, or the insulating film 22 may be provided after the terminal electrode 23 is provided on the inner surface 21a of the chip main body 21.

The insulating film 12 and the insulating film 22 used in the step (a) and the step (b) are configured by containing the inorganic material or the organic material. The inorganic material used in the insulating film, for example, is silicon oxide (SiO₂), silicon nitride (SiN), silicon oxynitride (SiON), or the like. In a case where the inorganic material such as silicon oxide is used in the insulating film, it is possible to prepare the semiconductor device with a finer configuration. Since it is easy to firmly bond the inorganic materials when attaching the insulating films in the following step (c), it is possible to increase a bonding strength between semiconductor substrates, and improve connection reliability as the semiconductor device.

The organic material used in the insulating film, for example, is polyimide, a polyimide precursor (for example, polyimide amic ester or a polyamic acid), polyamide imide, benzocyclobutene (BCB), polybenzoxazole (PBO), or a PBO precursor. Such an organic material, for example, has an elastic modulus lower than that of the inorganic material such as silicon oxide (SiO₂), and is a soft material. By using such an organic material, even in a case where there is fine debris on the insulating film when attaching the insulating films in the following step (c), it is possible to prevent a bond failure due to the debris by absorbing the debris in the insulating film, and reliably attach the insulating films. The elastic modulus of the organic material configuring the insulating film 12 and the insulating film 22, for example, may be 7.0 GPa or less, may be 5.0 GPa or less, may be 3.0 GPa or less, may be 2.0 GPa or less, or may be 1.5 GPa or less. Here, the elastic modulus indicates a Young's modulus. The thermal expansion coefficient of the organic material configuring the insulating film 12 and the insulating film 22 may be preferably 70 ppm/K or less, and even more preferably 50 ppm/K or less.

Since the organic material used in the insulating film is liquid or soluble in a solvent, each of the insulating films can be easily formed as a thin film by spin coating or the like. Further, such an organic material has heat resistance, thereby being capable of withstanding a temperature (for example, a high temperature of 300° C. or higher) when bonding the terminal electrode 13 to the terminal electrode 23 in the following step (d), and the bonding between the insulating films is not degraded by the high temperature. As the organic material configuring the insulating film 12 and the insulating film 22, a photosensitive resin, a thermosetting non conductive film (NCF), or a thermosetting resin may be used. Such an organic material may be an underfill material. The insulating film 12 and the insulating film 22 may be an insulating film containing both of the inorganic material and the organic material, and for example, a part (for example, the surface side) of the insulating film may be formed of the organic insulating material, and the remaining part may be formed of the inorganic insulating material.

In the steps (a) and (b), the surface of the insulating film 12 on which the terminal electrode 13 of the first semiconductor chip 10 is provided, and the surface of the insulating film 22 on which the terminal electrode 23 of the second semiconductor chip 20 is provided may be ground by using a chemical mechanical polishing (CMP) method. In such a grinding treatment, for example, each of the first semiconductor chip 10 and the second semiconductor chip 20 may be ground by the CMP method in the condition of selectively deeply grinding the terminal electrode 13 and the terminal electrode 23 consisting of copper or the like, or may be ground by the CMP method such that the surface of each of the terminal electrode 13 and the terminal electrode 23 is coincident with the surface of each of the insulating film 12 and the insulating film 22. According to such grinding, debris on the surface of the first semiconductor chip 10 and the second semiconductor chip 20 is also removed. In the grinding treatment, grinding may be performed such that the thickness of the insulating film 12 is the same as the thickness of the insulating film 22, and for example, grinding may be performed such that the thickness of the insulating film 22 is greater than the thickness of the insulating film 12. On the other hand, grinding may be performed such that the thickness of the insulating film 22 is less than the thickness of the insulating film 12.

[Step (c) and Step (d)]
In the step (c) and the step (d), as illustrated in FIG. 3, the second semiconductor chips 20 are mounted (provided) on the first semiconductor chip 10. When the second semiconductor chips are provided, the second semiconductor chips 20 are positioned such that the terminal electrode 23 of the second semiconductor chip 20 faces the corresponding terminal electrode 13 of the first semiconductor chip 10. For such positioning, an alignment mark or the like may be provided on the first semiconductor chip 10.

More specifically, as illustrated in FIGS. 4A and 4B, the step (c) is a step of attaching the insulating film 12 of the first semiconductor chip 10 and the insulating film 22 of the second semiconductor chip 20 to each other. In the step (c), the second semiconductor chip 20 is positioned with respect to the first semiconductor chip 10 after removing an organic substance or a metal oxide attached onto the surface of the second semiconductor chip 20, and in a case where such positioning is ended, the insulating film 22 of each of the second semiconductor chips 20 is attached to the insulating film 12 of the first semiconductor chip 10 by hybrid bonding. In this case, attaching may be performed after homogeneously heating the insulating film 22 of the second semiconductor chip 20 and the insulating film 12 of the first semiconductor chip 10. It is preferable that a temperature difference between the first semiconductor chip 10 and the second semiconductor chip 20 when attached, for example, is 10° C. or lower. An insulating bonding portion S1 in which the insulating film 12 and the insulating film 22 are bonded is formed by heating bonding at such a homogeneous temperature, and the second semiconductor chip 20 is mechanically firmly attached to the first semiconductor chip 10. By the heating bonding at a homogeneous temperature, the misregistration or the like is less likely to occur in the bonding area, and it is possible to perform high-accuracy bonding. In such an attachment stage, the terminal electrode 13 of the first semiconductor chip 10 and the terminal electrode 23 of the second semiconductor chip 20 are separated from each other and not connected (however, positioned). The second semiconductor chip 20 may be attached to the first semiconductor chip 10 by other bonding methods, and for example, may be bonded by room-temperature bonding or the like.

[Step (d)]
The step (d) is a step of bonding the terminal electrode 13 of the first semiconductor chip 10 and the terminal electrode 23 of the second semiconductor chip 20. In the step (d), as illustrated in FIG. 4B, in a case where the attaching of the step (c) is ended, as hybrid bonding, the terminal electrode 13 of the first semiconductor chip 10 and the terminal electrode 23 of the second semiconductor chip 20 are bonded by applying predetermined heat or a pressure, or both (also refer to FIG. 4C). In a case where the terminal electrode 13 and the terminal electrode 23 are composed of copper, an annealing temperature in the step (d) is preferably 150° C. or higher and 400° C. or lower, and more preferably 200° C. or higher and 300° C. or lower. According to such a bonding treatment, an electrode bonding portion S2 in which the terminal electrode 13 and the terminal electrode 23 corresponding thereto are bonded is formed, and the terminal electrode 13 and the terminal electrode 23 are mechanically and electrically firmly bonded. FIG. 4C illustrates a state where the insulating bonding portion S1 and the electrode bonding portion S2 are formed. The bonding of the electrode in the step (d) is performed after the attaching of the step (c), and may be performed simultaneously with the attaching of the step (c). After that, as illustrated in FIG. 5A, a semi-finished product 1a in which the second semiconductor chips 20 are bonded to the first semiconductor chip 10 is formed.
[Step (e)]
The step (e) is a step of encapsulating the second semiconductor chips 20 provided on the first semiconductor chip 10 with the encapsulating resin to form the encapsulating body 30. In the step (e), as illustrated in FIG. 5A, in a case where the second semiconductor chips 20 are provided on the first semiconductor chip 10, encapsulating is performed to cover the second semiconductor chips 20 with the encapsulating material. Accordingly, as illustrated in FIG. 5B, the encapsulating body 30 covering the second semiconductor chips 20 is formed. As a material configuring the encapsulating body 30, for example, an epoxy resin or an acrylic resin can be exemplified, and the encapsulating body 30 can be formed by encapsulating the second semiconductor chips 20 with such a resin, and then, curing the encapsulating resin material with heat or light.
[Step (f)]
The step (f) is a step of grinding the surface 30a of the encapsulating body 30. In the step (f), as illustrated in FIG. 5B, the surface 30a of the encapsulating body 30 is ground after the encapsulating body 30 is formed. In the step of grinding, the encapsulating body 30 is ground such that the surface roughness (a Ra value) of the surface 30a of the encapsulating body 30 is 1 μm or less, even more preferably 0.5 μm or less, and most preferably 0.1 μm or less. In this case, as a grinding method, for example, a method such as a grinder for processing an electronic material or chemical mechanical polishing (CMP) can be used. When performing such grinding, the grinding can be performed within a range where the encapsulated second semiconductor chips 20 are not exposed. In this case, the grinding may be performed such that the thickness of the encapsulating body 30 between the surface 30a of the encapsulating body 30 and the second semiconductor chip 20 is 300 μm or less, even more preferably 250 μm or less, and most preferably 200 μm or less. Alternatively, the grinding may be performed to the extent that the surfaces of the encapsulated second semiconductor chips (on a side opposite to the surface for forming the terminal electrode and the insulating layer) are exposed. The surface roughness (the Ra value) used herein, for example, is calculated by observation with an electron microscope, and indicates arithmetic mean surface roughness (JIS B 0601-2001).
[Step (g)]
The step (g) is a step of forming at least one via hole 31 in the encapsulating body 30 formed of the encapsulating resin. In the step (g), as illustrated in FIG. 5B, in a case where the encapsulating body 30 is formed, as illustrated in FIG. 5C, each via hole 31 is formed in a predetermined area of the encapsulating body 30 by laser, wet etching or dry etching, or the like. The via hole 31 is a through hole extending to the terminal electrode 13 of the first semiconductor chip 10 from the surface 30a of the encapsulating body 30, and a part of the terminal electrode 13 is exposed into the via hole 31. A method for preparing the via hole is not limited to the method described above, and may be other methods.
[Step (h)]
The step (h) is a step of filling the conductive material in the via hole 31 such that electric connection to at least one of the terminal electrode 13 and terminal electrode 23 is attained to form the conduction via 32. In the step (h), as illustrated in FIG. 5C, in a case where the via hole 31 is formed in the encapsulating body 30, as illustrated in FIG. 6A, a conductive paste is filled in the via hole 31 by printing or the like. The conductive paste, for example, is configured by containing copper or the like. Accordingly, the conduction via 32 is formed. Such a conduction via 32 has a pillar element, and is capable of attaining a high aspect ratio. One end of the conduction via 32 is exposed to the surface 30a of the encapsulating body 30, and the other end is electrically connected to the terminal electrode 13 (or the terminal electrode 23). The conduction via 32 may be formed by plating. In the step (h), the wiring layer 33 is formed on the surface 30a of the encapsulating body 30 after the conduction via 32 is formed. The wiring layer 33 may be formed together with the conduction via 32, or may be separately formed after the conduction via 32 is formed, by plating, printing of a conductive paste, or the like.
[Step (i)]
The step (i) is a step of forming the re-distribution layer 40 on the surface 30a of the encapsulating body 30. In the step (i), as illustrated in FIG. 6A, in a case where the conduction via 32 and the wiring layer 33 are formed in the encapsulating body 30, as illustrated in FIG. 6B, the re-distribution layer 40 is formed on the surface 30a of the encapsulating body 30. The re-distribution layer 40 is a layer for widening the terminal pitch of the terminal electrode 13 of the first semiconductor chip 10, and for example, is composed of the insulating layer 41 such as polyimide, and the wiring electrode 42 such as copper wiring in the insulating layer 41. In the step of forming the re-distribution layer 40, the formation of the insulating layer and the formation of the wiring layer are repeated a predetermined number of times to form a wiring layer for performing pitch conversion. One end 42a of the wiring electrode 42 in the re-distribution layer 40 is connected to the conduction via 32 or the wiring layer 33, and the other end 42b is exposed to the outside from the insulating layer 41. The bump 50 described below is connected to the other end 42b of the wiring electrode 42. The outer insulating layer 43 may be further provided outside the re-distribution layer 40, or may be configured such that the other ends 42b of the wiring electrodes 42 connected to the respective bumps 50 are not electrically connected to each other. In such a production method, since the grinding treatment is performed to reduce the unevenness or the surface roughness of the surface of the encapsulating body 30 after the encapsulating body 30 is formed, it is easy to construct a fine re-distribution layer on the encapsulating body 30.
[Step (j)]
The step (j) is a step of forming the bump 50 on an outer surface 40a of the re-distribution layer 40 positioned on a side opposite to the encapsulating body 30. In the step (j), in a case where the re-distribution layer 40 is formed, as illustrated in FIGS. 6B and 6C, the bump 50 is formed on the outer surface 40a of the re-distribution layer 40 to be connected to the other end 42b of the wiring electrode 42 exposed from the insulating layer 41. Since the bump 50, for example, is a solder ball, and is connected to the terminal on one end 42a of which the terminal pitch is widened by the re-distribution layer 40, the terminal electrode 13 of the first semiconductor chip 10 is pitch-converted (widened) and connected to the bump 50. As described above, the semiconductor device 1 illustrated in FIG. 1 can be obtained.

As described above, according to the method for producing a semiconductor device according to this embodiment, the first semiconductor chip 10 and the second semiconductor chip 20 are bonded by so-called hybrid bonding, and then, the second semiconductor chip 20 is encapsulated, and the conduction via 32 is formed in the encapsulating body 30. Since the conduction via 32 is formed after encapsulating, it is possible to form the conduction via 32 with a high density and a high aspect ratio. Accordingly, in three-dimensional packaging in which the second semiconductor chip 20 is provided on the first semiconductor chip 10, it is possible to perform high-density packaging.

In the method for producing a semiconductor device according to this embodiment, at least one of the insulating film 12 and the insulating film 22 may include the inorganic insulating material. In this case, it is possible to prepare the semiconductor device with a finer configuration. Both of the insulating film 12 and the insulating film 22 may include the inorganic insulating material, and in this case, the inorganic materials are likely to be firmly bonded, and it is possible to increase a bonding strength between the semiconductor chips, and improve the connection reliability as the semiconductor device.

In the method for producing a semiconductor device according to this embodiment, at least one of the insulating film 12 and the insulating film 22 may include the organic insulating material. In this case, unnecessary particles (debris) or the like attached onto the chip surface are absorbed in the insulating film by the organic material that is a comparatively soft material, and it is possible to reduce a connection failure between the semiconductor chips.

In the method for producing a semiconductor device according to this embodiment, in the step of attaching, the insulating film 12 and the insulating film 22 may be bonded by the room-temperature bonding. In this case, the insulating film 12 and the insulating film 22 can be easily bonded without considering thermal expansion or the like. Since the bonding is performed at a room temperature, the influence of heat on the first semiconductor chip 10 and the second semiconductor chip 20 may not be considered.

The method for producing a semiconductor device according to this embodiment may further include the step of grinding the surface 30a of the encapsulating body 30. In this case, since the unevenness or a variation in the surface roughness on the surface 30a of the encapsulating body 30 is reduced, it is possible to more accurately and easily form the re-distribution layer 40, the normal wiring layer 33, or the like with a high density. In this case, in the step of grinding, the encapsulating body may be ground such that the surface roughness (Ra) of the encapsulating body 30 is 1 μm or less, even more preferably 0.5 μm or less, and most preferably 0.1 μm or less. Accordingly, it is possible to form wiring with a fine pattern shape. In the step of grinding, the encapsulating body 30 may be ground such that the thickness of the encapsulating body 30 between the surface 30a of the encapsulating body 30 and the second semiconductor chip 20 is 300 μm or less, even more preferably 250 μm or less, and most preferably 200 μm or less. Alternatively, the surface of the second semiconductor chip (on a side opposite to the terminal electrode) may be exposed. Accordingly, it is possible to more reliably reduce the size of a package, reduce warpage, and improve heat dissipation.

The method for producing a semiconductor device according to this embodiment may further include the step of forming the re-distribution layer 40 on the encapsulating body 30. In this case, it is possible to easily convert the wiring pitch of the first semiconductor chip 10 or the like into the wiring pitch of an external device such as a wiring substrate.

The method for producing a semiconductor device according to this embodiment may further include the step of forming the bump 50 on the outer surface 40a of the re-distribution layer 40 positioned on a side opposite to the encapsulating body 30. Accordingly, it is possible to easily attach the semiconductor device 1 to the external device such as the wiring substrate.

In the method for producing a semiconductor device according to this embodiment, the encapsulating material used in the step of encapsulating may be the epoxy resin or the acrylic resin. In this case, it is possible to reliably and easily perform the encapsulating of the second semiconductor chip 20.

In the method for producing a semiconductor device according to this embodiment, in the step of forming the via hole, the plurality of via holes 31 may be formed around the second semiconductor chip 20, and the terminal electrode 13 of the first semiconductor chip 10 is exposed to the plurality of via holes 31. Then, in the step of filling the conductive material, the conductive material is filled in each of the plurality of via holes 31 such that electric connection to the terminal electrode 13 is attained. Accordingly, it is possible to provide the conduction via 32 with a higher density, and more reliably connect the first semiconductor chip 10 to the external device or the like. It is also possible to easily prepare the conduction via 32 with a high aspect ratio.

In the method for producing a semiconductor device according to this embodiment, the second semiconductor chip 20 is a chip having a surface area smaller than that of the first semiconductor chip 10, and the plurality of second semiconductor chips 20 are bonded to the first semiconductor chip 10. In the step of encapsulating, the plurality of second semiconductor chips 20 provided on the first semiconductor chip 10 are collectively encapsulated with the encapsulating resin. Accordingly, since it is possible to bond two or more second semiconductor chips 20 to one first semiconductor chip 10, it is possible to perform the three-dimensional packaging with a higher density.

In the semiconductor device according to this embodiment, the first semiconductor chip 10 and the second semiconductor chip 20 are firmly bonded by so-called hybrid bonding, and the conduction via 32 is formed in the encapsulating body 30 encapsulating the second semiconductor chip 20. Since the conduction via 32 is formed in the encapsulating body 30, it is possible to form the conduction via 32 with a high density. Accordingly, in the three-dimensional packaging in which the second semiconductor chip 20 is provided on the first semiconductor chip 10, it is possible to perform the high-density packaging.

The semiconductor device according to this embodiment may further include the re-distribution layer 40 provided on the surface of the encapsulating body 30 on a side opposite to the first semiconductor chip 10. The re-distribution layer 40 is electrically connected to the terminal electrode 13 of the first semiconductor chip 10 by the conduction via 32. Accordingly, it is possible to easily convert the wiring pitch of the first semiconductor chip 10 or the like into the wiring pitch of the external device such as the wiring substrate.

The embodiment of the present disclosure has been described, but the present invention is not limited to the embodiment described above, and may be suitably modified within a range not departing from the gist thereof.

### REFERENCE SIGNS LIST

1: semiconductor device, 10: first semiconductor chip, 11: chip main body (first chip main body), 12: insulating film (first insulating film), 13: terminal electrode (first electrode), 20: second semiconductor chip, 21: chip main body (second chip main body), 22: insulating film (second insulating film), 23: terminal electrode (second electrode), 30: encapsulating body, 30a: surface, 31: via hole, 32: conduction via, 33: wiring layer, 40: re-distribution layer, 50: bump.

1. A method for producing a semiconductor device, comprising:
preparing a first semiconductor chip including a first chip main body, and a first insulating film and a first electrode provided on one surface of the first chip main body;
preparing at least one second semiconductor chip including a second chip main body, and a second insulating film and a second electrode provided on one surface of the second chip main body;
attaching the first insulating film of the first semiconductor chip and the second insulating film of the second semiconductor chip to each other;
bonding the first electrode of the first semiconductor chip to the second electrode of the second semiconductor chip;
encapsulating the second semiconductor chip provided on the first semiconductor chip with an encapsulating resin;
forming at least one via hole in an encapsulating body formed of the encapsulating resin; and
filling a conductive material in the via hole such that electric connection to at least one of the first electrode and the second electrode is attained to form a conduction via.

2. The method for producing a semiconductor device according to claim 1,
wherein at least one of the first insulating film and the second insulating film includes an inorganic insulating material.

3. The method for producing a semiconductor device according to claim 1,
wherein at least one of the first insulating film and the second insulating film includes an organic insulating material.

4. The method for producing a semiconductor device according to claim 1, further comprising
grinding a surface of the encapsulating body.

5. The method for producing a semiconductor device according to claim 4,
wherein in the grinding, the encapsulating body is ground such that surface roughness of the encapsulating body is 0.1 μm or less.

6. The method for producing a semiconductor device according to claim 4,
wherein in the grinding, the encapsulating body is ground such that a thickness of the encapsulating body between the surface of the encapsulating body and the second semiconductor chip is 300 μm or less.

7. The method for producing a semiconductor device according to claim 1, further comprising
forming a re-distribution layer on the encapsulating body.

8. The method for producing a semiconductor device according to claim 7,
wherein the re-distribution layer is electrically connected to the first electrode of the first semiconductor chip by the conduction via formed of the conductive material.

9. The method for producing a semiconductor device according to claim 7, further comprising
forming a bump on an outer surface of the re-distribution layer positioned on a side opposite to the encapsulating body.

10. The method for producing a semiconductor device according to claim 1,
wherein the encapsulating resin used in the encapsulating is an epoxy resin or an acrylic resin.

11. The method for producing a semiconductor device according to claim 1,
wherein in the forming of the via hole, a plurality of the via holes are formed around the second semiconductor chip, and
wherein the first electrode of the first semiconductor chip is exposed to the plurality of via holes, and
wherein in the filling of the conductive material, the conductive material is filled in each of the plurality of via holes such that electric connection to the first electrode is attained.

12. The method for producing a semiconductor device according to claim 1,
wherein the second semiconductor chip is a chip having a surface area smaller than that of the first semiconductor chip,
wherein a plurality of second semiconductor chips are bonded to the first semiconductor chip, and
wherein in the encapsulating, the plurality of second semiconductor chips provided on the first semiconductor chip are collectively encapsulated with the encapsulating resin.

13. A semiconductor device, comprising:
a first semiconductor chip including a first chip main body, and a first insulating film and a first electrode provided on one surface of the first chip main body;
a second semiconductor chip including a second chip main body, and a second insulating film and a second electrode provided on one surface of the second chip main body, the second semiconductor chip being provided on the first semiconductor chip;
an encapsulating body covering the second semiconductor chip on the first semiconductor chip; and
a conduction via filled in a via hole provided in the encapsulating body to be electrically connected to at least one of the first electrode and the second electrode.

14. The semiconductor device according to claim 13, further comprising
a re-distribution layer provided on a surface of the encapsulating body on a side opposite to the first semiconductor chip,
wherein the re-distribution layer is electrically connected to the first electrode of the first semiconductor chip by the conduction via.
